(19) United States
(12) Patent Application Publication
(10) Pub. No.: US 2026/0334079 A1
(43) Pub. Date: Oct. 22, 2026

(54) PHONON-COUPLED THERMOELECTRIC LIQUID HEAT EXTRACTION ARCHITECTURE

(71) Applicant: FAIZAN AHMED, SAN JOSE, CA (US)

(72) Inventor: FAIZAN AHMED, SAN JOSE, CA (US)

(21) Appl. No.: 19/555,261

(22) Filed: Mar. 3, 2026

Related U.S. Application Data
(60) Provisional application No. 63/772,745, filed on Mar. 17, 2025.

(51) Int. Cl. H10N 10/13; H10N 10/17; H10N 10/82; H10N 10/852; H10N 19/00

(52) U.S. Cl. CPC H10N 10/13; H10N 10/17; H10N 10/82; H10N 10/852; H10N 19/00

(57) ABSTRACT

A thermoelectric cooling assembly comprises a copper water block having internal flow channels configured for liquid coolant circulation, a plurality of thermoelectric modules, and a plurality of solder bonds. Each thermoelectric module comprises bismuth telluride semiconductor pellets electrically connected in series by copper traces and disposed between a top ceramic plate and a bottom ceramic plate. Each solder bond permanently attaches the bottom ceramic plate of a respective thermoelectric module directly to a top surface of the copper water block. The thermoelectric modules are arranged in a linear array along the top surface. During operation, waste heat from the thermoelectric modules is transferred into the copper water block and removed by coolant circulating through the internal flow channels as part of a closed-loop cooling circuit.

### CLAIM OF PRIORITY

This application claim priority to U.S. Provisional Patent Application No. 63/772,745, filed on Mar. 17, 2025 and titled advanced thermal management systems with a thermoelectric water block. This provisional patent application is hereby incorporated by reference in its entirety.

### BACKGROUND

### Field of the Invention

### Field of the Invention

The present invention relates generally to portable temperature-controlled storage systems, and more particularly to an Phonon-Coupled Thermoelectric Liquid Heat Extraction Architecture.

### Background

Temperature-sensitive materials, particularly in medical and biological applications, require precise temperature control during storage and transport. Traditional cooling systems rely on compressors, refrigerants, or ice packs that are bulky, inefficient, and unable to maintain consistent temperatures. Thermoelectric cooling devices utilizing the Peltier effect of-fer solid-state cooling alternatives, but their effectiveness is critically dependent on efficient heat removal from the hot side of the thermoelectric module.

Existing thermoelectric cooling implementations face significant thermal management challenges. Conventional thermoelectric modules are typically attached to heat sinks or cold plates using thermal interface materials (TIM) such as thermal paste or adhesive pads. These thermal interface materials introduce thermal resistance, degrade over time through pump-out effects and thermal cycling, and create points of mechanical and thermal failure. The cumulative thermal resistance of these interfaces significantly reduces the coefficient of performance (COP) and overall cooling capacity of thermoelectric systems.

Furthermore, existing thermoelectric cooling assemblies lack scalability and mod-ularity. Single thermoelectric modules provide limited cooling capacity, while attempts to scale cooling power through multiple modules result in complex assemblies with multiple thermal interfaces, each contributing additional thermal resistance. Current approaches also fail to efficiently integrate water cooling with thermoelectric modules in a unified, compact architecture suitable for portable applications.

There exists a need for a thermoelectric cooling assembly that eliminates degradable thermal interface materials, provides permanent high-conductivity thermal pathways, enables modular scalability of cooling capacity, and integrates liquid cooling in a compact form factor. The present invention addresses these needs through a novel thermoelectric water block assembly utilizing direct solder bonding of thermoelectric modules to copper cold plates.

### BRIEW SUMMARY OF THE INVENITON

In one aspect, a thermoelectric cooling assembly comprises a copper water block having a top surface, a bottom surface, and internal flow channels configured for liquid coolant circulation, a plurality of thermoelectric modules, and a plurality of solder bonds. Each thermo-electric module comprises bismuth telluride semiconductor pellets electrically connected in series by copper traces and disposed between a top ceramic plate and a bottom ceramic plate. Each solder bond permanently attaches the bottom ceramic plate of a respective thermoelectric module directly to the top surface of the copper water block. The plurality of thermoelectric modules are arranged in a linear array along the top surface of the copper water block. The copper water block provides a unified thermal management system in which waste heat from the plurality of thermoelectric modules is absorbed by liquid coolant circulating through the internal flow channels as part of a closed-loop cooling circuit.

### BRIEF DESCRIPTION OF THE DRAWINGS

FIG. 1 is a top view of example embodiment of a portable temperature-controlled enclosure, according to some embodiments.

FIGS. 2 and 3 are isometric views of example embodiment of a portable temperature-controlled enclosure, according to some embodiments.

FIG. 4 is a front view of example embodiment of a portable temperature-controlled enclosure, according to some embodiments.

FIG. 5 is a side view of example embodiment of a portable temperature-controlled enclosure, according to some embodiments.

FIG. 6-9 illustrate various example views of an aluminum cooling chamber portable unit, according to some embodiments.

FIG. 6 illustrates a top-view of aluminum cooling chamber portable unit, according to some embodiments.

FIG. 7 illustrates a isometric-view of aluminum cooling chamber portable unit, according to some embodiments.

FIG. 8 illustrates a rear-view of aluminum cooling chamber portable unit, according to some embodiments.

FIG. 9 illustrates a side-view of aluminum cooling chamber portable unit, according to some embodiments.

FIG. 10 is a block diagram of a sample computing environment that can be uti-lized to implement various embodiments.

FIG. 11 illustrates a logical view of a portable temperature-controlled enclosure, according to some embodiments.

FIG. 12 illustrates a top plan view of the thermoelectric water block assembly, according to some embodiments.

FIG. 13 illustrates an isometric detail view of a single thermoelectric module assembly, according to some embodiments.

FIG. 14 illustrates a top plan view of the thermoelectric water block assembly, according to some embodiments.

FIG. 15 illustrates a front elevation view of the thermoelectric water block assembly, according to some embodiments.

The Figures described above are a representative set and are not an exhaustive with respect to embodying the invention.

### DESCRIPTION

Disclosed are a system, method, and article of manufacture for a with a thermo-electric water block. The following description is presented to enable a person of ordinary skill in the art to make and use the various embodiments. Descriptions of specific devices, techniques, and applications are provided only as examples. Various modifications to the examples described herein can be readily apparent to those of ordinary skill in the art, and the general principles defined herein may be applied to other examples and applications without departing from the spirit and scope of the various embodiments.

Reference throughout this specification to ‘one embodiment,’ ‘an embodiment,’ ‘one example,’ or similar language means that a particular feature, structure, or characteristic described in connection with the embodiment is included in at least one embodiment, according to some embodiments. Thus, appearances of the phrases ‘in one embodiment,’ ‘in an embodiment,’ and similar language throughout this specification may, but do not necessarily, all refer to the same embodiment.

Furthermore, the described features, structures, or characteristics of the invention may be combined in any suitable manner in one or more embodiments. In the following description, numerous specific details are provided, such as examples of programming, software modules, user selections, network transactions, database queries, database structures, hardware modules, hardware circuits, hardware chips, etc., to provide a thorough understanding of embodiments of the invention. One skilled in the relevant art can recognize, however, that the invention may be practiced without one or more of the specific details, or with other methods, components, materials, and so forth. In other instances, well-known structures, materials, or operations are not shown or described in detail to avoid obscuring aspects of the invention.

The schematic flow chart diagrams included herein are generally set forth as logical flow chart diagrams. As such, the depicted order and labeled steps are indicative of one embodiment of the presented method. Other steps and methods may be conceived that are equivalent in function, logic, or effect to one or more steps, or portions thereof, of the illus-trated method. Additionally, the format and symbols employed are provided to explain the logical steps of the method and are understood not to limit the scope of the method. Although various arrow types and line types may be employed in the flow chart diagrams, and they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown. Appendix A includes additional information for implementing various embodiments.

### DEFINITIONS

Example definitions for some embodiments are now provided.

Acrylonitrile butadiene styrene (ABS) is a common plastic polymer.

High-density polyethylene (HDPE) or polyethylene high-density (PEHD) is a polyethylene thermoplastic made from petroleum.

The thermo-electric effect is the presence of heating or cooling at an electrified junction of two different conductors. When a current is made to flow through a junction between two conductors, A and B, heat may be generated or removed at the junction. Thermo-electric cooling uses the Peltier effect to create a heat flux between the junction of two different types of materials. A thermoelectric cooler, heater, or thermoelectric heat pump is a solid-state active heat pump which transfers heat from one side of the device to the other, with consumption of electrical energy, depending on the direction of the current.

Thermal control material (TCM) is a substance with a high heat of fusion which, melting and solidifying at a certain temperature, is capable of storing and releasing large amounts of energy. Heat is absorbed or released when the material changes from solid to liquid and vice versa. Example TCM materials can include, inter alia: organic (paraffin and nonparaf-fin), inorganic (salt hydrates and metallic alloys), and eutectic (mixture of two or more TCM components: organic, inorganic, and both).

Polypropylene (PP) is a thermoplastic polymer used in a wide variety of applications. It is produced via chain-growth polymerization from the monomer propylene.

Press fit or friction fit is a fastening between two parts which is achieved by friction after the parts are pushed together, rather than by any other means of fastening.

Temperature sensors can include mechanical temperature sensors, electrical temperature sensors, integrated circuit sensors, medometers, etc.

Thermoelectric effect is the direct conversion of temperature differences to electric voltage and vice versa via a thermocouple. A thermoelectric device creates voltage when there is a different temperature on each side. Conversely, when a voltage is applied to it, heat is transferred from one side to the other, creating a temperature difference. At the atomic scale, an applied temperature gradient causes charge carriers in the material to diffuse from the hot side to the cold side.

6061-T6 aluminum is a precipitation-hardened aluminum alloy containing mag-nesium and silicon, heat-treated to the T6 temper to provide increased strength, machinability, and corrosion resistance.

3003-H14 aluminum is a work-hardened aluminum alloy containing manganese, cold-worked to the H14 temper to increase strength while retaining high thermal conductivity and corrosion resistance.

Controlled dip-coating can be a deposition process in which a part is immersed in a liquid coating bath and withdrawn at a controlled rate such that a uniform wet film forms on the surface.

Spray-deposition can be a surface-coating process that atomizes a liquid precur-sor and directs droplets toward a target surface to form a continuous coating layer.

A nanostructured adhesion primer layer can be a thin film comprising nanoscale features configured to promote mechanical or chemical bonding between a substrate and an overlying coating.

A hydrocarbon material layer having a thermal diffusivity can be a coating comprising organic molecules configured to exhibit a rate of internal heat transport characterized by its thermal diffusivity.

Thermal diffusivity can be a material property defined as the ratio of thermal conductivity to volumetric heat capacity (α=k/(ρ·Cp)), indicating the rate at which heat spreads through a substance.

Hydrocarbon coating mass can be a quantity of applied hydrocarbon coating ma-terial measured as the total mass present on a coated surface.

### Example Smart Refrigerator Exterior Views

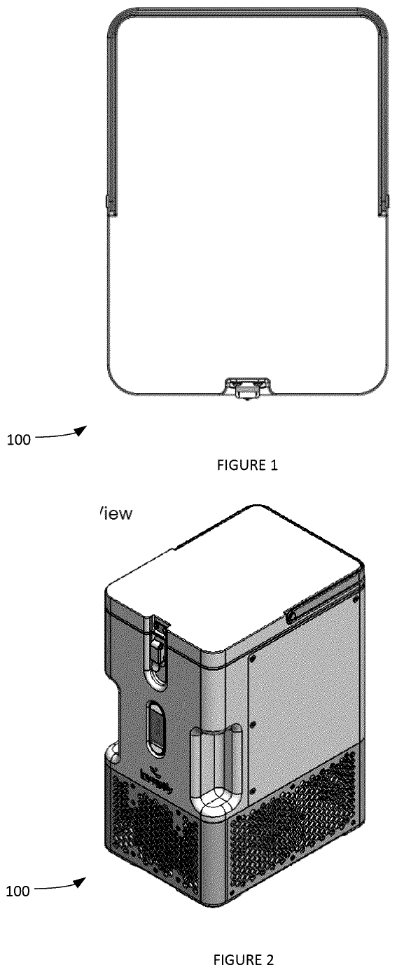

FIGS. 1-5 provide series of views of an example embodiment of a portable temperature-controlled enclosure 100, according to some embodiments. The series of views includes a set of orthographic views (e.g. top, front, side, and isometric) of the portable temperature-controlled enclosure according to one embodiment. The example embodiment of a portable temperature-controlled enclosure 100 can be a top loaded system. Portable temperature-controlled enclosure 100 can include an optimized solid-state cooling system (e.g. see infra). Portable temperature-controlled enclosure 100 provides a portable temperature-controlled enclosure utilizing an innovative solid-state cooling system with optimized thermal management. Portable temperature-controlled enclosure 100 combines advanced thermoelectric cooling technology with sophisticated control systems to achieve superior temperature stability and extended battery operation.

Portable temperature-controlled enclosure 100 comprises several key components working in concert: a precision-engineered payload chamber for storing temperature-sensitive materials, an optimized thermoelectric cooling system with angular mounting configuration, an integrated thermal control material(TCM) chamber for thermal buffering, and a sophisticated heat dissipation system including honeycomb ventilation. These components are managed by advanced monitoring and control systems, all supported by extended battery-powered operation capability.

The top-loading portable temperature-controlled enclosure 100 represents a breakthrough in portable refrigeration technology, utilizing solid-state cooling principles to maintain precise temperature control. The top-loading portable temperature-controlled enclosure 100 distinguishes itself through the complete elimination of traditional cooling infrastructure components such as compressors, refrigerant gases, cooling coils, ice packs, or gel packs.

Example physical specifications of the top-loading portable temperature-controlled enclosure 100 are now discussed. The top-loading portable temperature-controlled enclosure 100 payload capacity, by way of example, can be a one (1) liter. The top-loading portable temperature-controlled enclosure 100 can include a top-loading design with example dimensions of 107.78 mm×119.92 mm×166.84 mm.

Access to the top-loading portable temperature-controlled enclosure 100 can be via a top-mounted lid providing full access to internal chamber. Construction of The top-loading portable temperature-controlled enclosure 100 can include precision-engineered aluminum chamber with integrated cooling system.

An example Core Cooling Technology of the top-loading portable temperature-controlled enclosure 100 is now discussed. The top-loading portable temperature-controlled enclosure 100 employs an advanced solid-state cooling mechanism based on semiconductor physics. As a cooling principle, the top-loading portable temperature-controlled enclosure 100 utilizes an electron mobility differential between semiconductor materials. By way of operation, the top-loading portable temperature-controlled enclosure 100 uses an electric current pas-sage through dual-semiconductor junction.

The thermal control during electron transition between materials is implemented to optimize cooling efficiency. The top-loading portable temperature-controlled enclosure 100 can achieve target temperature (2 °C) within 2-hour initialization period. The top-loading portable temperature-controlled enclosure 100 implements temperature maintenance to maintain 2-8 °C range for 72 hours without external power.

An example Thermal Management System of the internal payload chamber incorporates a sophisticated thermal management design. As seen below, the top-loading portable temperature-controlled enclosure 100 includes a chamber construction that includes payload 104. Here, the material composition can include a specialized heat-absorbing material combined with aluminum. The top-loading portable temperature-controlled enclosure 100 utilizes thermal spreading via an engineered aluminum structure for optimal temperature distribution. The top-loading portable temperature-controlled enclosure 100 performs heat absorption via a material matrix for thermal energy management.

The top-loading portable temperature-controlled enclosure 100 provides dy-namic temperature control. Primary cooling is performed via a solid-state semiconductor chip (e.g. discussed infra). Supplementary cooling can be performed via a thermal mass buffer system. Hybrid operation between thermal mass and active cooling Response system can be used for temperature maintenance. Automated cooling bursts for temperature deviation compensation can be performed.

The top-loading portable temperature-controlled enclosure 100 can include a power and environmental adaptation power system 1102. The top-loading portable temperature-controlled enclosure 100 includes an input compatibility, by way of example of a Universal AC power (110V/220V) and an integrated charging system. Battery operation can be for 72-hour autonomous operation capability.

Optimized power consumption during steady-state operation can be obtained using bi-directional temperature control capability. For example, in a winter mode operation, the top-loading portable temperature-controlled enclosure 100 functions in extreme cold environments (−20 °C to −30 °C). Thermal management systems 1104 of the top-loading portable temperature-controlled enclosure 100 can maintains 2-8 °C in both hot and cold ambient conditions. An example environmental range enables The top-loading portable temperature-controlled enclosure 100 to be functional across extreme temperature variations.

The top-loading portable temperature-controlled enclosure 100 includes a monitoring and communication system 1106 for temperature monitoring. Real-time temperature tracking is implemented across continuous internal temperature measurement. The top-loading portable temperature-controlled enclosure 100 includes a digital display for current temperature indication. The top-loading portable temperature-controlled enclosure 100 includes an alert system for temperature deviations. The top-loading portable temperature-controlled enclosure 100 includes a communication infrastructure 1108 that can include an integrated LTE module with SIM card and/or GPS location tracking capability. The top-loading portable temperature-controlled enclosure 100 can perform data transmission intervals (e.g. at 4-5 minutes. The top-loading portable temperature-controlled enclosure 100 also includes cloud connectivity for remote monitoring. A backup SD card storage system can be included for offline data logging. The top-loading portable temperature-controlled enclosure 100 includes a Data Management module 1110 for continuous temperature logging and location tracking and recording. The top-loading portable temperature-controlled enclosure 100 can also perform automated cloud data synchronization.

The top-loading portable temperature-controlled enclosure 100 includes an Operation and Performance Temperature Performance module that manages an initial cooldown (e.g. 2 hours to reach target temperature with a temperature range: 2-8 °C maintenance and operation duration of 72 hours on battery power).

A thermal interface material utilizes a high thermal conductivity compound with controlled thickness application and full surface coverage verification. Mounting pressure can be maintained at 30-40 PSI through a spring-loaded mechanism, ensuring even pressure distribution across the chip surface and compensation for thermal expansion and contraction in some example embodiments.

The top-loading configuration represents a significant advancement in portable temperature-controlled storage, combining innovative solid-state cooling technology with sophisticated thermal management and monitoring systems. The design achieves exceptional effi-ciency and reliability while maintaining precise temperature control across varied environmental conditions.

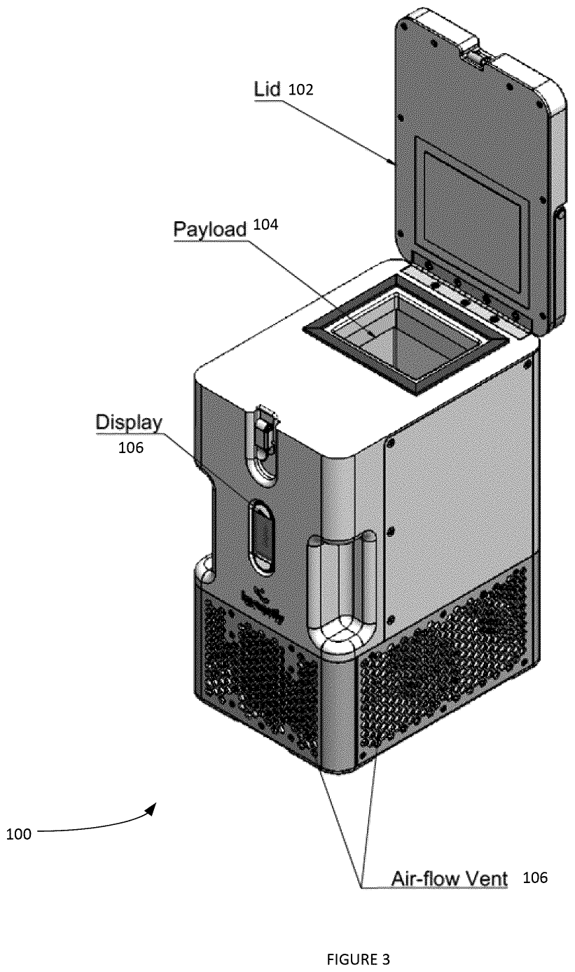

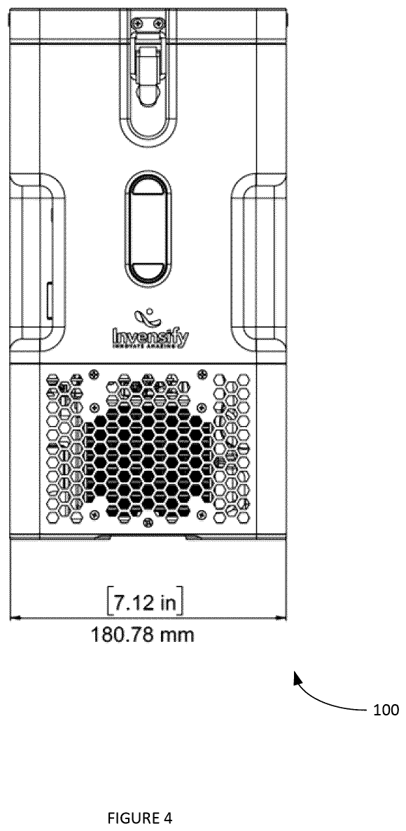

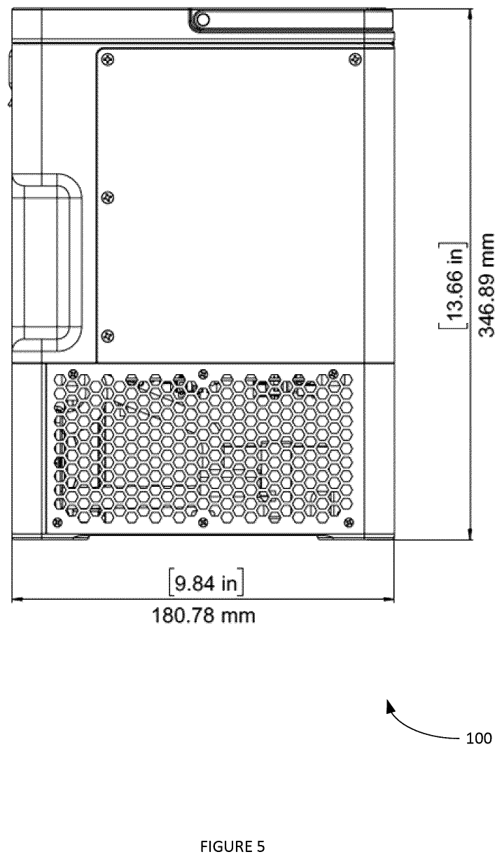

More specifically, FIG. 1 is a top view of example embodiment of a portable temperature-controlled enclosure 100, according to some embodiments. FIGS. 2 and 3 are isometric views of example embodiment of a portable temperature-controlled enclosure 100, according to some embodiments. FIG. 4 is a front view of example embodiment of a portable temperature-controlled enclosure 100, according to some embodiments. FIG. 5 is a side view of example embodiment of a portable temperature-controlled enclosure 100, according to some embodiments.

In one embodiments, portable temperature-controlled enclosure 100 can have a top-loading configuration with example payload dimensions: 3.2″×4.1″×5.5″. An example top opening capacity can be one (1) liter. Overall dimensions, by way of example, can be 107.78 mm×119.92 mm×166.84 mm. Portable temperature-controlled enclosure 100 provides a top access lid for payload (e.g. medications, etc.) insertion.

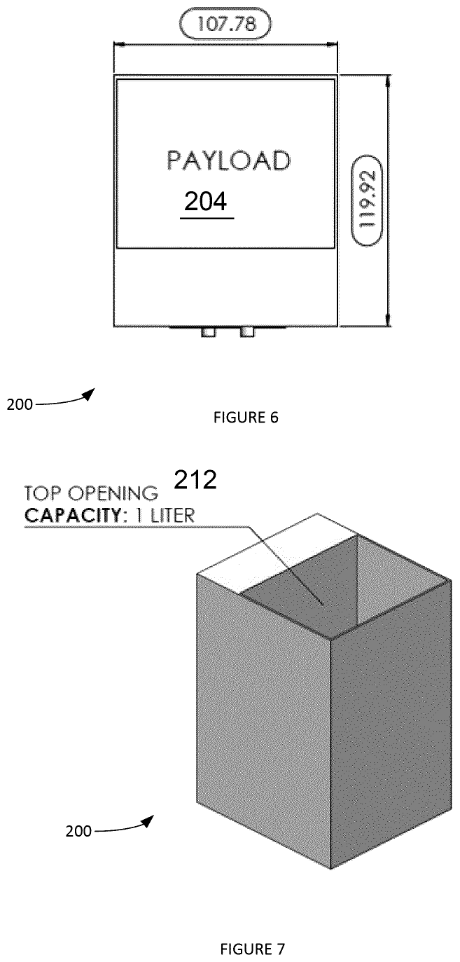

FIG. 6-9 illustrate various example views of an aluminum cooling chamber portable unit 200, according to some embodiments. Aluminum cooling chamber portable unit 200 can be the internal cooling/heating system of portable temperature-controlled enclosure 100.

Aluminum cooling chamber portable unit 200 of portable temperature-controlled enclosure 100 comprises a sophisticated thermoelectric cooling mechanism wherein electrical power is transmitted through a strategically positioned semiconductor chip 202 mounted at a calculated angular orientation relative to the aluminum payload chamber 204. The semiconductor chip 202 incorporates a material combination wherein electrons traverse between different semiconductor elements, creating an thermal control effect at the material junction interfaces. This thermal control phenomenon, occurring at the precise locations where the material composition transitions, facilitates the cooling process through electron mobility differentials between the semiconductor materials.

The thermal management system utilizes direct thermal coupling between the semiconductor chip 202 and an aluminum payload chamber 204, whereby the thermal control at the material junctions actively extracts heat from the payload area through the aluminum wall interface. The extracted thermal energy is subsequently transferred to a closed-loop cooling system 206 comprising fluid-carrying pipes 208 directly coupled to the posterior surface of the semiconductor chip (e.g. can include a heat sink system). The cooling loop 206 employs either water or antifreeze as the working fluid, circulating through an engineered pipe network via an integrated pump mechanism.

The system's thermal circuit can be completed through a fan-assisted heat exchanger configuration 214, wherein the heated working fluid from the cooling loop 206 is actively cooled before being recirculated through the system. The angular mounting of the semiconductor chip, deliberately oriented at a calculated angle rather than perpendicular to the payload chamber, achieves enhanced cooling distribution by optimizing the radius of coolness spread and increasing the effective surface area coverage. This angular configuration demon-strably improves the speed and uniformity of temperature distribution compared to traditional perpendicular mounting arrangements.

The thermal control system can operate in a dual-power configuration, initially utilizing wall power for the cooldown phase until the target temperature (typically 2 °C) is achieved, at which point the system transitions to battery power through a lithium polymer battery assembly capable of maintaining temperature control for 72 hours of autonomous operation. The internal configuration includes various top-loading variants (e.g. via top opening 212, etc.) while maintaining identical operational principles, with the semiconductor chip positioning optimized for each configuration to maximize cooling efficiency through enhanced radial distribution patterns.

The angular orientation of the semiconductor chip 202 relative to the payload chamber wall facilitates superior thermal spreading characteristics. The cooling effect disperses in a radial pattern rather than traditional linear distribution, resulting in more efficient coverage of the payload surface area and accelerated temperature equalization throughout the chamber. This geometric optimization of the semiconductor chip 202 placement enables the system to achieve more comprehensive thermal coverage compared to conventional perpendicular mounting configurations, as the angular positioning creates an expanded radius of cooling influence that enhances the overall heat absorption efficiency of the system.

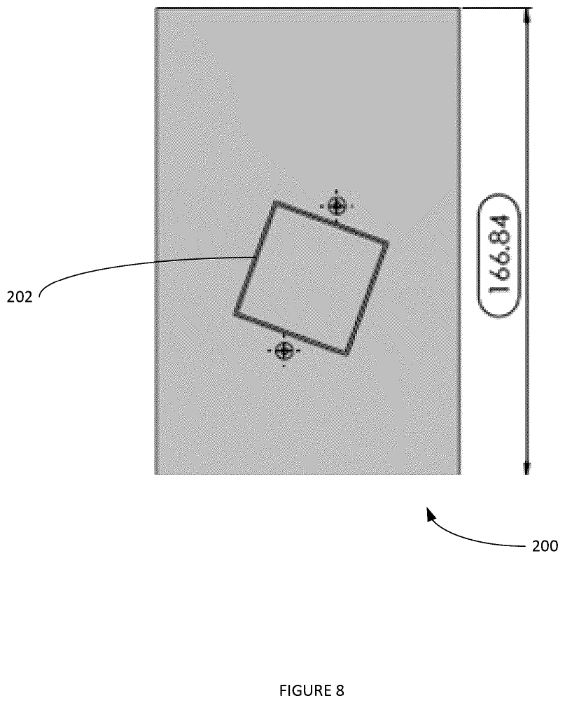

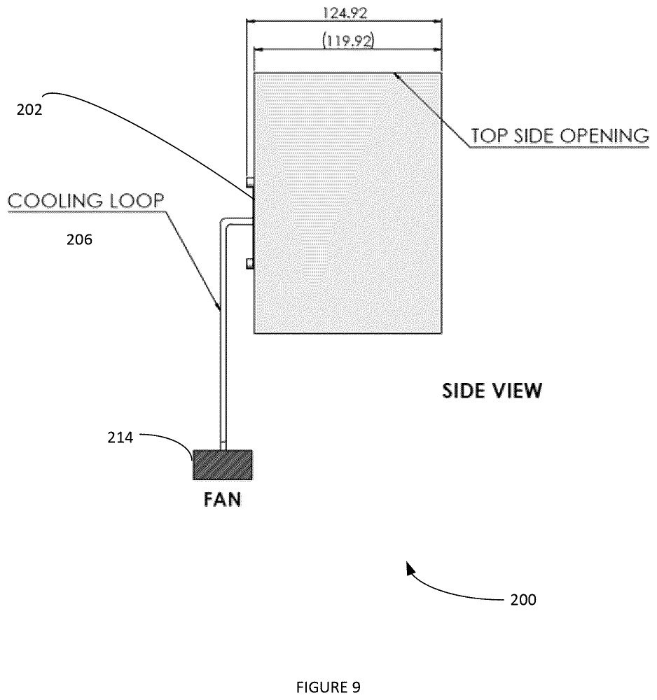

More specifically, FIG. 6 illustrates a top-view of aluminum cooling chamber portable unit 200, according to some embodiments. FIG. 7 illustrates a isometric-view of aluminum cooling chamber portable unit 200, according to some embodiments. FIG. 8 illustrates a rear-view of aluminum cooling chamber portable unit 200, according to some embodiments. FIG. 9 illustrates a side-view of aluminum cooling chamber portable unit 200, according to some embodiments.

### Example Computer Architecture And Systems

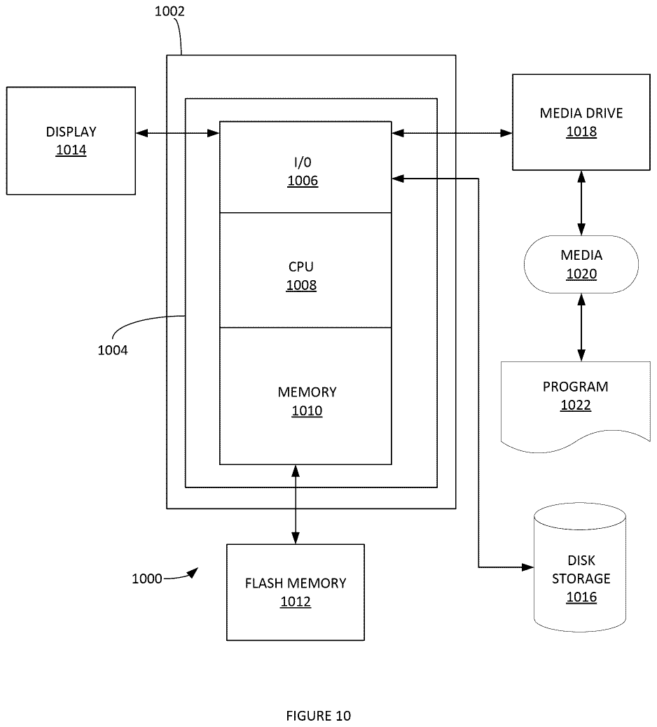

FIG. 10 depicts an exemplary computing system 1000 that can be configured to perform any one of the processes provided herein. In this context, computing system 1000 may include, for example, a processor, memory, storage, and I/O devices (e.g., monitor, keyboard, disk drive, Internet connection, etc.). However, computing system 1000 may include circuitry or other specialized hardware for carrying out some or all aspects of the processes. In some operational settings, computing system 1000 may be configured as a system that includes one or more units, each of which is configured to carry out some aspects of the processes either in software, hardware, or some combination thereof.

FIG. 10 depicts computing system 1000 with a number of components that may be used to perform any of the processes described herein. The main system 1002 includes a motherboard 1004 having an I/O section 1006, one or more central processing units (CPU) 1008, and a memory section 1010, which may have a flash memory card 1012 related to it. The I/O section 1006 can be connected to a display 1014, a keyboard and/or other user input (not shown), a disk storage unit 1016, and a media drive unit 1018. The media drive unit 1018 can read/write a computer-readable medium 1020, which can contain programs 1022 and/or data. Computing system 1000 can include a web browser. Moreover, it is noted that computing system 1000 can be configured to include additional systems in order to fulfill various functionali-ties. Computing system 1000 can communicate with other computing devices based on various computer communication protocols such a Wi-Fi, Bluetooth® (and/or other standards for ex-changing data over short distances includes those using short-wavelength radio transmissions), USB, Ethernet, cellular, an ultrasonic local area communication protocol, etc.

Thermo-electric cooler pump can be managed by a computing system in the portable smart refrigerator. The computing system can be coupled with an exterior display. Exterior display can display various parameters (e.g. temperature, battery power, etc.) of the portable smart refrigerator. Computing system can also be coupled with various other systems such as, inter alia: temperature sensors, digital clocks, Wi-Fi systems, etc.

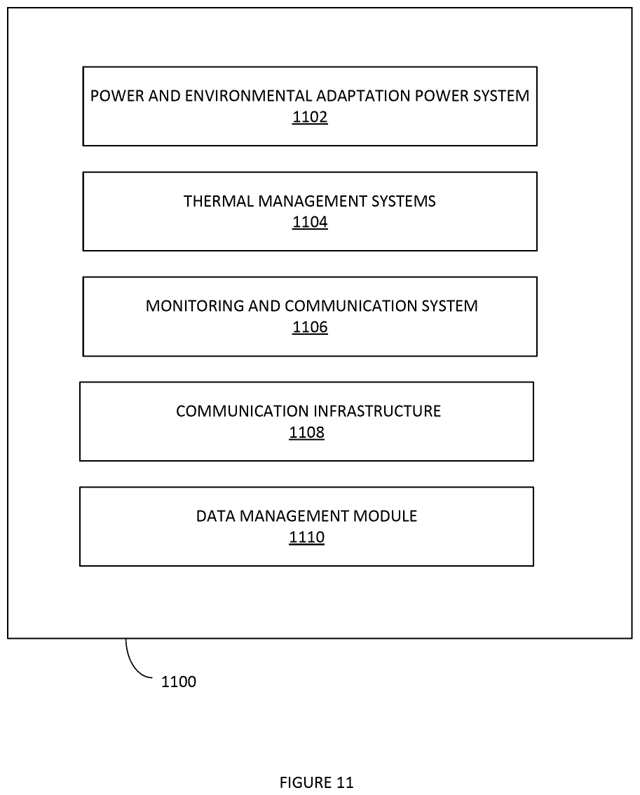

FIG. 11 illustrates a logical view 1100 of a portable temperature-controlled enclosure, according to some embodiments. Power and environmental adaptation power system 1102. The top-loading portable temperature-controlled enclosure 100 includes an input compatibility, by way of example of a Universal AC power (110V/220V) and an integrated charging system. Thermal management systems 1104 manage the temperature of top-loading portable temperature-controlled enclosure 100. Thermal management systems 110 of the top-loading portable temperature-controlled enclosure 100 can maintain 2-8 °C in both hot and cold ambient conditions. Monitoring and communication system 1106 for temperature monitoring. Real-time temperature tracking is implemented across continuous internal temperature measurement. The top-loading portable temperature-controlled enclosure 100 includes a digital display for current temperature indication. The top-loading portable temperature-controlled enclosure 100 includes an alert system for temperature deviations. The top-loading portable temperature-controlled enclosure 100 includes a communication infrastructure 1108 that can include an integrated LTE module with SIM card and/or GPS location tracking capability. The top-loading portable temperature-controlled enclosure 100 can perform data transmission intervals (e.g. at 4-5 minutes. The top-loading portable temperature-controlled enclosure 100 also includes cloud connectivity for remote monitoring. A backup SD card storage system can be included for offline data logging. The top-loading portable temperature-controlled enclosure 100 includes a Data Management module 1110 for continuous temperature logging and location tracking and recording.

Additional information on chip positioning is now discussed. The innovative cooling system centers around a precisely engineered 40 mm×40 mm semiconductor chip that represents a significant advancement in portable refrigeration technology. This chip, comprising multiple semiconductor junctions arranged in an optimized pattern, is mounted at a carefully calculated 20-degree angle relative to the payload chamber wall, deviating from traditional perpendicular mounting approaches. This specific angular orientation was chosen to maximize the cooling efficiency through enhanced radial distribution patterns.

The mounting configuration creates a sophisticated thermal management system where the chip interfaces directly with the aluminum chamber wall for maximum thermal conductivity. This direct coupling is maintained by a spring-loaded mechanism that ensures a consistent 30-40 PSI mounting pressure, crucial for optimal heat transfer. The interface between the chip and wall utilizes a high thermal conductivity compound with carefully controlled thickness and verified full surface coverage.

The 20-degree mounting angle serves a critical purpose in the system's operation. Unlike conventional perpendicular mounting, which typically results in linear cooling distribution, this angular orientation creates an expanded radius of cooling influence. This radial distribution pattern enables more comprehensive coverage of the payload surface area and facilitates faster temperature equalization throughout the chamber. The result is a more efficient and effective cooling system that achieves superior thermal coverage compared to traditional mounting configurations.

In the top-loaded configuration, the chip is positioned lower, near the midsection of the wall, with the temperature sensor strategically placed inside the payload wall towards the bottom side. This positioning was specifically chosen to optimize the cooling effect in relation to the temperature sensor location. The entire setup demonstrates a carefully engineered ap-proach to thermal management, where each component's position has been optimized for maximum efficiency.

The semiconductor chip's design and mounting create a cooling effect that disperses in a radial pattern rather than a traditional linear distribution. This radial dispersion is particularly effective because it provides more uniform coverage across the payload area. The angular mounting effectively increases the total area over which the cooling effect spreads, resulting in more efficient temperature control throughout the chamber. This innovative ap-proach to chip mounting and cooling distribution represents a significant advancement in portable refrigeration technology, offering improved performance over conventional perpendicular mounting systems.

The system's overall design reflects a deep understanding of thermal dynamics and practical engineering considerations. By combining the precise 40 mm×40 mm chip dimen-sions with the 20-degree mounting angle and strategic positioning relative to temperature sensors, the system achieves optimal cooling performance while maintaining efficient use of space within the portable unit. The careful attention to mounting pressure, thermal compound application, and interface design ensures reliable and consistent performance, making this cooling system particularly well-suited for portable applications requiring precise temperature control.

### Advanced Thermal Management Systems with a Thermoelectric Water Block

The present invention provides a novel thermoelectric water block assembly that integrates multiple thermoelectric cooling modules with a copper cold plate through permanent solder bonding, creating a unified, high-performance cooling solution that eliminates the thermal interface materials used in conventional designs.

The assembly comprises a precision-engineered copper water block with integrated internal flow channels for liquid cooling. Multiple thermoelectric modules, each consist-ing of bismuth telluride (Bi₂Te₃) semiconductor pellets arranged between copper traces, are permanently soldered directly to the top surface of the copper block. This direct solder attachment eliminates thermal paste, adhesive pads, and other degradable thermal interface materials, creating a permanent, high-conductivity thermal pathway with minimal thermal resistance.

Each thermoelectric module in the exemplary embodiment comprises 50 pairs of semiconductor pellets, with each pellet measuring 1 mm×1 mm in area and 1 mm in height. The pellets are arranged within a 20 mm×20 mm footprint with 0.25 mm gaps between adjacent pellets. The top and bottom ceramic plates are 0.2 mm thick, with copper traces of 0.05 mm thickness connecting the pellets in an electrical series configuration.

The copper water block features inlet and outlet ports for continuous liquid circulation. During operation, electrical current applied to the thermoelectric modules generates a temperature differential through the Peltier effect: the top surface becomes cold (suitable for payload cooling), while heat is transferred to the bottom surface. This waste heat conducts directly through the solder interface into the copper block, where circulating water absorbs and transports it to an external radiator for dissipation.

Unlike phase-change cooling systems utilizing heat pipes where liquid vaporizes at low pressure to transport heat, this water block design employs continuous liquid circulation without phase change. The liquid remains in its fluid state throughout the cooling loop, requiring active pumping but offering superior heat removal capacity for high-load applications.

The modular architecture allows multiple thermoelectric modules to be arranged in a linear array, enabling scalable cooling capacity. This configuration provides uniform cooling across an extended surface area, making the assembly suitable for applications requiring consistent temperature control over larger thermal zones. The unified housing integrates all modules into a single compact unit, maximizing thermal efficiency while minimizing system complexity.

The assembly represents a significant advancement over prior art by combining permanent metallurgical bonding, modular scalability, and integrated water cooling in a compact form factor specifically designed for portable refrigeration applications requiring high reliability and extended operational life.

The invention utilizes direct solder bonding to permanently attach thermoelectric cooling modules to a copper water block substrate, eliminating degradable thermal interface materials (TIM) such as thermal paste or adhesive pads. This metallurgical bond creates a permanent, low-resistance thermal pathway that does not degrade through thermal cycling, pump-out effects, or aging, thereby maintaining consistent coefficient of performance (COP) throughout the operational lifetime of the device.

Multiple thermoelectric modules are arranged in a linear series configuration within a unified copper water block housing, enabling scalable cooling capacity. This modular architecture allows selective configuration of cooling power by varying the number of integrated modules while maintaining a compact form factor, unlike conventional discrete assemblies requiring individual mounting and thermal interface preparation for each module.

The copper water block serves dual functions as both the structural framework and the primary heat sink for multiple thermoelectric modules. Internal flow channels permit continuous liquid circulation across all modules simultaneously, creating a unified thermal management system wherein waste heat from multiple thermoelectric junctions is absorbed by a single closed-loop cooling circuit.

By replacing conventional thermal interface materials with direct solder bonds, the invention eliminates the cumulative thermal resistance that occurs in multi-module systems. Each solder interface exhibits thermal conductivity approaching that of the base materials themselves, whereas conventional TIM introduces 0.5-2.0 K·cm²/W of thermal resistance per interface. In a multi-module configuration, this elimination of interface resistance provides expo-nential improvement in overall system thermal performance.

The invention achieves high-density integration of multiple thermoelectric modules (50 pairs per module, 1 mm×1 mm pellet geometry, 20 mm×20 mm footprint) within a continuous water-cooled assembly. The compact configuration with 0.25 mm inter-pellet spacing maximizes cooling capacity per unit volume while maintaining manufacturability and reliability.

The solder-bonded construction creates a hermetically sealed, mechanically robust assembly resistant to vibration, thermal shock, and mechanical stress. Unlike assemblies relying on thermal paste or adhesive bonding which require periodic maintenance and TIM re-placement, the soldered configuration provides maintenance-free operation over extended service intervals.

The system employs continuous liquid circulation in a closed loop without re-liance on phase-change phenomena, distinguishing it from heat pipe architectures. This ap-proach enables higher heat flux removal rates suitable for high-power thermoelectric configurations while maintaining operational simplicity and eliminating pressure-sensitive phase-change mechanisms.

Multiple thermoelectric modules arranged in series along the water block enable extended cooling zones or staged temperature reduction, allowing applications requiring cooling across elongated payloads or multi-zone temperature control. The unified water block architecture permits this serialization without requiring complex plumbing or multiple independent cooling circuits.

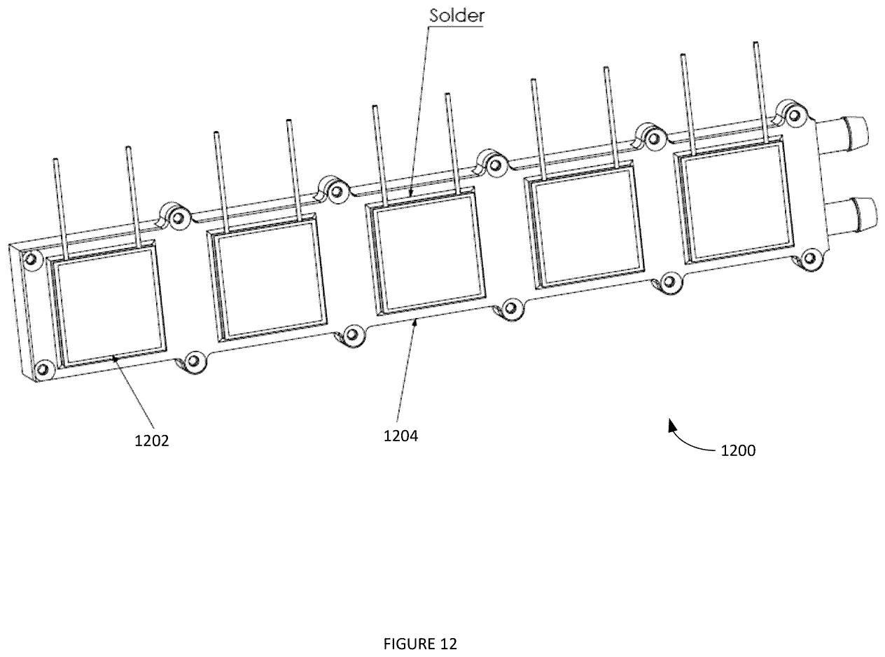

FIG. 12 illustrates a top plan view of the thermoelectric water block assembly 1200, according to some embodiments. The assembly comprises a unified copper water block structure 1200 having a plurality of thermoelectric modules 1202 permanently affixed thereto via solder bonds 1204.

The copper water block 1200 forms an elongated rectangular housing with integrated internal flow channels configured for liquid coolant circulation. The water block 1200 includes a pair of cylindrical fluid ports positioned at one end of the assembly, providing inlet and outlet connections for the closed-loop cooling circuit. The water block 1200 is fabricated from high-purity copper to maximize thermal conductivity and facilitate efficient heat transfer from the thermoelectric modules to the circulating coolant.

A plurality of thermoelectric modules 1202 are disposed along the longitudinal axis of the copper water block 1200 in a linear array configuration. In the exemplary embodiment illustrated, five thermoelectric modules 1202 are positioned in series, though alternative embodiments may employ fewer or additional modules depending on the required cooling capacity. Each thermoelectric module 1202 comprises a plurality of bismuth telluride semiconductor pellets arranged between copper traces and encapsulated between ceramic plates, as described in detail elsewhere in this specification.

Each thermoelectric module 1202 is permanently bonded to the top surface of the copper water block 1200 by means of a solder bond 1204. The solder bonds 1204 create metallurgical connections between the bottom ceramic plate of each thermoelectric module 1202 and the copper substrate of the water block 1200. These solder bonds 1204 eliminate the need for conventional thermal interface materials such as thermal paste or adhesive pads, thereby reducing thermal resistance and preventing degradation over time. The solder material employed in the solder bonds 1204 exhibits thermal conductivity approaching that of the copper substrate itself, by way of example, ranging from 50-80 W/(m·K), resulting in thermal interface resistance of less than 0.2 K·cm²/W per interface.

Each thermoelectric module 1202 further includes a plurality of electrical connection terminals extending from the top surface thereof, configured to receive electrical power for operation of the Peltier cooling effect. The electrical terminals enable independent or collective electrical connection of the thermoelectric modules 1202 depending on the desired operating configuration.

The modular architecture illustrated in FIG. 12 demonstrates the scalability of the invention. The linear arrangement of multiple thermoelectric modules 1202 along a single unified water block 1200 enables cooling coverage across an extended surface area while maintaining a compact overall footprint. This configuration is particularly advantageous for applications requiring uniform temperature control across elongated payload chambers or multi-zone cooling applications.

The unified construction of the copper water block 1200 with integrated flow channels permits simultaneous cooling of all thermoelectric modules 1202 via a single coolant circulation path, eliminating the complexity and thermal resistance penalties associated with multiple independent cooling circuits. During operation, electrical current applied to the thermoelectric modules 1202 generates cold zones at their upper surfaces while transferring waste heat to their lower surfaces. This waste heat conducts through the solder bonds 1204 into the copper water block 1200, where it is absorbed by the circulating liquid coolant and transported to an external heat exchanger for dissipation.

The permanent solder-bonded construction illustrated in FIG. 12 provides superior mechanical robustness compared to assemblies relying on compressive force or adhesive bonding. The metallurgical bonds formed by the solder 1204 resist degradation from thermal cycling, vibration, and mechanical shock, ensuring consistent thermal performance throughout the operational lifetime of the device. This construction is particularly suited for portable refrigeration applications requiring high reliability and extended maintenance-free operation.

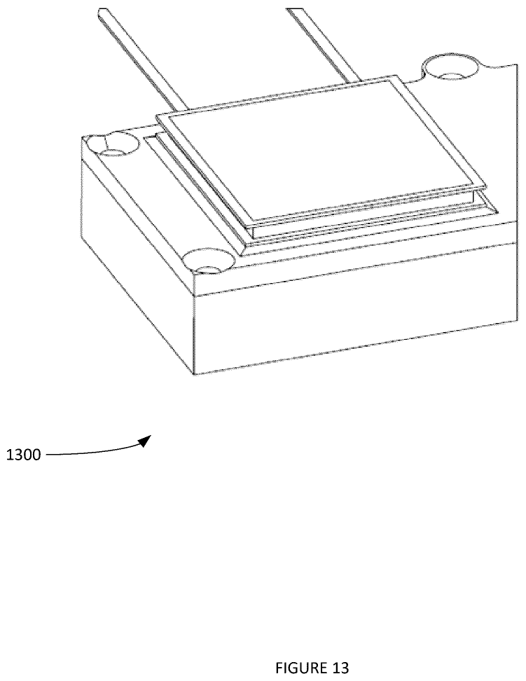

FIG. 13 illustrates an isometric detail view of a single thermoelectric module assembly 1300, according to some embodiments. This figure provides a magnified perspective of the construction showing a single thermoelectric module mounted on a copper water block substrate.

The assembly 1300 comprises a copper water block base forming a rectangular platform with integrated water circulation features. Two cylindrical fluid ports extend from op-posing sides of the copper block, providing inlet and outlet connections for liquid coolant flow. The copper block includes mounting features at its corners, visible as raised cylindrical bosses, which facilitate secure attachment of the assembly within a larger cooling system.

A thermoelectric module is positioned centrally on the top surface of the copper water block 1300. The thermoelectric module exhibits a multi-layer construction, with a visible stack of ceramic plates sandwiching the internal semiconductor pellet array. The layered structure shown in the detail view illustrates the sandwich construction typical of thermoelectric devices: bottom ceramic plate, internal pellet and trace assembly, and top ceramic plate.

The thermoelectric module is permanently affixed to the copper water block surface via a solder bond, though the solder interface itself is not separately labeled in this view as it resides between the bottom ceramic plate and the copper substrate. Two electrical connection terminals extend vertically from the top surface of the thermoelectric module, configured to receive electrical power for operation.

The compact profile illustrated in FIG. 13 demonstrates the efficient integration of the thermoelectric cooling element with the water-cooled heat sink. The relatively thin vertical dimension of the assembly enables integration into space-constrained applications while maintaining high thermal performance through the direct solder-bonded interface.

The water circulation ports positioned on opposite sides of the copper block enable series or parallel flow configurations when multiple such assemblies are combined into a larger array. The symmetrical design with centrally positioned thermoelectric module ensures balanced thermal distribution and uniform cooling performance.

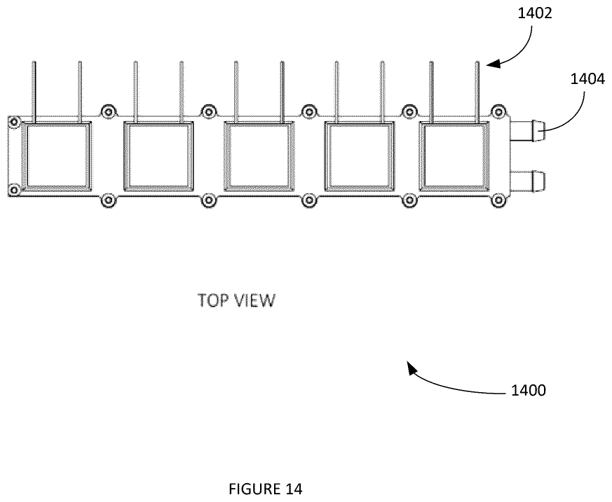

FIG. 14 illustrates a top plan view of the thermoelectric water block assembly 1400, according to some embodiments. This figure presents an alternative perspective empha-sizing the modular architecture and electrical connection scheme.

The assembly 1400 comprises a unified copper water block structure extending longitudinally along the length of the assembly. A plurality of thermoelectric modules are disposed in a linear array along the top surface of the copper water block 1400. In the exemplary embodiment illustrated, five thermoelectric modules are positioned in series, uniformly spaced along the longitudinal axis.

Each thermoelectric module includes electrical connection terminals 1402 extending vertically from its top surface. The electrical terminals 1402 provide connection points for supplying electrical power to the thermoelectric modules, enabling operation of the Peltier cooling effect. In the illustrated embodiment, each module includes a pair of electrical terminals 1402, corresponding to the positive and negative electrical connections required for DC power input. The vertical orientation of the terminals 1402 facilitates electrical connection via wire harnesses or printed circuit board interfaces positioned above the assembly.

Fluid ports 1404 are positioned at one end of the copper water block 1400, providing inlet and outlet connections for the liquid cooling circuit. The fluid ports 1404 comprise cylindrical passages extending perpendicular to the main body of the water block, configured for connection to flexible tubing or rigid piping of an external cooling loop. The positioning of both fluid ports 1404 at the same end of the assembly simplifies plumbing integration and minimizes the footprint required for fluid connections.

The top view clearly illustrates the modular scalability of the design. The linear arrangement of thermoelectric modules along a single continuous water block 1400 enables extended cooling coverage while maintaining a unified thermal management system. This configuration eliminates the need for multiple independent water blocks and associated plumbing complexity that would be required in conventional multi-module cooling assemblies.

The uniform spacing between adjacent thermoelectric modules visible in the top view provides clearance for the electrical terminals 1402 and ensures balanced thermal distribution along the length of the water block 1400. The integrated construction shown in FIG. 14 demonstrates how multiple cooling zones can be created along a single thermal management platform, particularly advantageous for applications requiring temperature control across elongated payload geometries or multi-zone refrigeration chambers.

The copper water block 1400 features mounting provisions at its perimeter, enabling secure mechanical attachment to payload chambers, enclosure walls, or structural frames. The low-profile design minimizes vertical space requirements while the elongated form factor maximizes cooling coverage area, making the assembly particularly suited for portable refrigeration systems where space efficiency is critical.

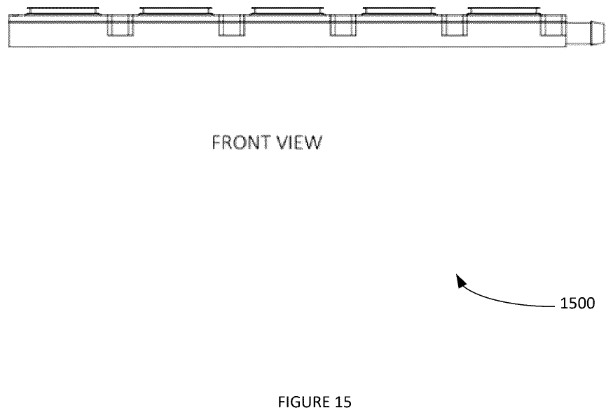

FIG. 15 illustrates a front elevation view of the thermoelectric water block assembly 1500, according to some embodiments. This orthographic projection provides a side perspective that emphasizes the low-profile construction and the relationship between the thermoelectric modules and the underlying copper water block substrate.

The assembly 1500 comprises an elongated copper water block base extending horizontally across the length of the assembly. The water block exhibits a relatively thin vertical profile, optimized for compact integration while maintaining sufficient internal volume for effective liquid coolant circulation. A cylindrical fluid port is visible at the right end of the assembly, projecting laterally from the water block body to provide fluid connection capability.

A plurality of thermoelectric modules are positioned atop the copper water block 1500 in a linear series arrangement. In the exemplary embodiment shown, five thermoelectric modules are visible, each exhibiting a stacked, layered construction. The front view clearly illustrates the multi-layer nature of each thermoelectric module, showing the thin profile of the ceramic plates and internal pellet assembly that characterize thermoelectric device construction.

Electrical connection terminals extend vertically upward from the top surface of each thermoelectric module. The front elevation perspective shows these terminals as vertical projections, illustrating their height relative to the thermoelectric module body and their positioning to facilitate electrical connection from above the assembly. Each module includes a pair of terminals visible in this view, corresponding to the positive and negative electrical connections required for DC power input.

The uniform height of all thermoelectric modules visible in the front view demonstrates the precision of the manufacturing and assembly process. The consistent module positioning ensures that when a payload chamber or cold plate is positioned atop the assembly 1500, thermal contact is achieved uniformly across all modules, preventing localized thermal resistance due to uneven contact pressure.

The low vertical profile illustrated in FIG. 15 is particularly advantageous for portable refrigeration applications where overall system height is constrained. The compact construction enables integration of the thermoelectric water block assembly 1500 into enclo-sures with limited vertical clearance while maintaining high cooling capacity through the multi-module array configuration.

The front view also reveals the mechanical stability of the assembly, with the continuous copper water block base providing a rigid structural platform upon which the thermoelectric modules are mounted. This unified construction eliminates the alignment and toler-ance stack-up issues that would occur in assemblies using discrete, individually mounted cooling modules.

The spacing between adjacent thermoelectric modules visible in the front elevation allows clearance for the electrical terminals and facilitates air circulation around the module perimeters if required for supplementary convective cooling or to prevent condensation in humid environments. The systematic arrangement of modules along the water block 1500 enables uniform thermal distribution and balanced cooling performance across the entire length of the assembly.

An example integration of thermoelectric water block assembly with aluminum cooling chamber portable unit is now discussed. In one embodiment of the invention, the thermoelectric water block assembly 1200 is integrated into the aluminum cooling chamber portable unit 200 to provide enhanced cooling performance for portable refrigeration applications. The aluminum cooling chamber portable unit 200 comprises a payload chamber configured to receive and maintain temperature-sensitive materials within a controlled temperature range, typically between 2 °C and 8 °C for medical and pharmaceutical applications.

The thermoelectric water block assembly 1200 is thermally coupled to the aluminum cooling chamber portable unit 200 such that the top surfaces of the plurality of thermo-electric modules 1202 make direct thermal contact with the bottom surface or side wall of the aluminum cooling chamber portable unit 200. This thermal coupling enables heat extraction from the payload chamber of the aluminum cooling chamber portable unit 200 through the cold side of the thermoelectric modules 1202. The permanent solder bonds 1204 securing the thermoelectric modules 1202 to the copper water block 1200 ensure that waste heat generated at the hot side of the thermoelectric modules 1202 is efficiently conducted into the copper water block 1200 for removal by the circulating liquid coolant.

The copper water block 1200 of the thermoelectric water block assembly 1200 includes internal flow channels through which liquid coolant circulates continuously during operation. The liquid coolant absorbs thermal energy from the copper water block 1200 and transports this heat to an external radiator or heat exchanger positioned remotely from the aluminum cooling chamber portable unit 200. This closed-loop liquid cooling circuit provides superior heat removal capacity compared to passive heat sinks or air-cooled configurations, enabling the aluminum cooling chamber portable unit 200 to maintain precise temperature control even under high ambient temperature conditions.

In operation, electrical power is supplied to the plurality of thermoelectric modules 1202 of the thermoelectric water block assembly 1200, generating a temperature differential across each thermoelectric module 1202 through the Peltier effect. The cold sides of the thermoelectric modules 1202 actively cool the aluminum cooling chamber portable unit 200, extracting heat from the payload chamber and any contents therein. The waste heat transferred to the hot sides of the thermoelectric modules 1202 conducts through the permanent solder bonds 1204 into the copper water block 1200, where it is absorbed by the circulating liquid coolant and removed from the vicinity of the aluminum cooling chamber portable unit 200.

The modular architecture of the thermoelectric water block assembly 1200, comprising multiple thermoelectric modules 1202 arranged in a linear array, enables the cooling capacity to be matched to the thermal requirements of the aluminum cooling chamber portable unit 200. In embodiments requiring higher cooling capacity, additional thermoelectric modules 1202 may be incorporated into the thermoelectric water block assembly 1200. Conversely, for applications with lower cooling demands, fewer thermoelectric modules 1202 may be employed. This scalability allows a single unified copper water block 1200 design to serve multiple aluminum cooling chamber portable unit 200 configurations without requiring redesign of the liquid cooling infrastructure.

The integration of the thermoelectric water block assembly 1200 with the aluminum cooling chamber portable unit 200 provides several operational advantages. The permanent solder bonds 1204 eliminate thermal interface material degradation that would occur with conventional thermal paste or adhesive pad attachments, ensuring consistent cooling performance throughout the operational lifetime of the aluminum cooling chamber portable unit 200. The unified copper water block 1200 simplifies the liquid cooling circuit by enabling all thermoelectric modules 1202 to share a single coolant flow path, reducing system complexity and potential failure points. The compact profile of the thermoelectric water block assembly 1200 enables integration into space-constrained portable configurations while maintaining high cooling capacity through the multi-module array architecture.

In example embodiments, the thermoelectric water block assembly 1200 is positioned such that its longitudinal axis aligns with a major dimension of the aluminum cooling chamber portable unit 200, enabling the linear array of thermoelectric modules 1202 to provide cooling coverage across an extended surface area of the payload chamber. This configuration is particularly advantageous for elongated payload geometries or applications requiring uniform temperature distribution across a larger area. The electrical connection terminals 1402 extending from the thermoelectric modules 1202 facilitate connection to a power supply and control system that regulates the electrical current supplied to the thermoelectric water block assembly 1200 based on temperature feedback from sensors positioned within the aluminum cooling chamber portable unit 200.

In some embodiments, the permanent solder bonds 1204 form continuous metallurgical interfaces across substantially the entire contact area between each thermoelectric module 1202 and the copper water block 1200. This continuous bonding eliminates micro-scale air gaps present in compressive or paste-based assemblies, thereby minimizing interfacial phonon scattering and reducing thermal boundary resistance. The metallurgical bond ensures long-term thermal stability independent of mechanical compression forces, mounting torque variation, or material pump-out effects.

The copper water block 1200 is configured with internal microchannel or macrochannel coolant passages extending beneath each thermoelectric module 1202. These flow channels are arranged to promote uniform coolant distribution across the longitudinal axis of the assembly, thereby preventing localized thermal accumulation and ensuring consistent heat extraction from each thermoelectric junction. In some embodiments, the channels may include turbulence-inducing features, including ribs, fins, or serpentine pathways, to enhance convective heat transfer between the copper substrate and the circulating coolant.

In certain embodiments, the thermoelectric modules 1202 are electrically connected in series, parallel, or hybrid electrical configurations to enable selective control of cooling capacity, voltage requirements, and power efficiency. Independent electrical addressing of individual modules permits zonal thermal regulation, allowing different sections of the assembly to operate at different cooling intensities depending on localized thermal load conditions.

The unified copper water block 1200 serves as both a thermal conduction substrate and a structural alignment fixture, maintaining precise spatial positioning of the thermo-electric modules 1202. This integrated construction prevents misalignment or uneven contact that would otherwise introduce thermal inefficiencies or mechanical stress concentrations in conventional discrete module assemblies.

In some embodiments, the solder bonds 1204 comprise high-thermal-conductiv-ity solder alloys including indium-based, tin-silver-based, or tin-copper-based compositions selected to provide thermal conductivity exceeding 40 W/(m·K). The solder composition may further be selected to provide matched coefficients of thermal expansion between the ceramic plates of the thermoelectric modules and the copper water block substrate, thereby minimizing mechanical stress during thermal cycling.

The linear arrangement of thermoelectric modules 1202 illustrated in FIGS. 12, 14, and 15 enables scalable extension of the assembly length without requiring modification of the underlying cooling architecture. Additional thermoelectric modules may be incorporated by extending the copper water block 1200 and associated internal coolant channels, thereby enabling proportional scaling of cooling capacity while maintaining uniform thermal performance.

In some embodiments, the copper water block 1200 may be fabricated using ma-chining, brazing, additive manufacturing, or diffusion bonding techniques to form internal coolant channels with optimized geometries for thermal transfer efficiency. Additive manufacturing techniques may enable formation of complex internal channel geometries not achievable using conventional subtractive manufacturing methods.

The direct solder bonding of thermoelectric modules 1202 to the copper water block 1200 provides enhanced mechanical rigidity and resistance to vibration-induced degradation. This construction is particularly advantageous for portable or mobile refrigeration applications where mechanical shock, vibration, or orientation changes may occur during operation or transport.

In certain embodiments, the thermoelectric water block assembly 1200 is configured to operate in conjunction with a temperature monitoring and control system comprising one or more temperature sensors positioned in thermal communication with the cooled payload chamber. The control system may regulate electrical current supplied to the thermoelectric modules 1202 to maintain a predetermined temperature range, thereby providing active closed-loop thermal regulation.

The integrated construction of the thermoelectric water block assembly 1200 enables reduction in total thermal resistance between the cooled payload chamber and the circulating coolant compared to assemblies utilizing separate thermoelectric modules and discrete heat sinks. This reduction in thermal resistance improves coefficient of performance (COP), reduces electrical power consumption, and increases cooling efficiency.

The assembly 1200 may be configured such that the thermoelectric modules 1202 are positioned to provide substantially uniform thermal coverage across the interface surface of the aluminum cooling chamber portable unit 200. This uniform distribution prevents localized temperature gradients within the payload chamber, thereby ensuring consistent temperature control of temperature-sensitive contents.

In some embodiments, the copper water block 1200 further functions as an electromagnetic shielding structure for the thermoelectric modules 1202, providing electrical grounding and reducing electromagnetic interference with adjacent electronic components.

The disclosed architecture enables high-density thermoelectric integration within a compact footprint while maintaining efficient heat removal through continuous liquid circulation. This combination of direct metallurgical bonding, unified coolant circulation, and modular thermoelectric integration provides improved thermal performance, mechanical durability, and operational reliability compared to prior art thermoelectric cooling assemblies.

Phonon can be a quantized unit of lattice vibrational energy in a solid material, representing a collective vibrational mode of atoms in a crystalline or polycrystalline structure. In thermally conductive interfaces, phonons can act as primary heat carriers and can contribute to thermal transport across a material boundary. Phonon coupling can refer to a degree of vibrational-energy transmission between adjacent solids at an interface, such that lattice vibrations in a first material excite corresponding vibrations in a second material, thereby facilitating heat flow across the interface. Phonon scattering can refer to disruption of phonon propagation caused by defects, interfacial roughness, micro-scale voids, dissimilar acoustic impedances, and/or mismatched vibrational spectra, which can increase thermal boundary resistance. In some embodiments, a phonon-coupled interface can be implemented by a continuous metallurgical bond between a thermoelectric module surface and a heat-extraction substrate to reduce interfacial discontinuities that promote phonon scattering and to improve thermal conduction from a hot side of a thermoelectric module into a liquid-cooled heat-extraction structure.

In some embodiments, thermal transport through the thermoelectric water block assembly is governed by a combination of electron-mediated heat transport within electrically conductive regions and phonon-mediated heat transport within lattice-dominated regions, including the ceramic plates of the thermoelectric modules and the copper water block. Phonons can be treated as quantized lattice vibrations that carry thermal energy through solid materials, particularly through electrically insulating or partially insulating regions where electron transport is limited. Accordingly, the heat extracted from the hot side of the thermoelectric modules and transferred into the copper water block can be described, in part, as phonon energy propagating through the ceramic plate and into the bonded copper substrate.

In conventional assemblies using thermal interface material (TIM), the interface between a thermoelectric module and a heat sink can include micro-voids, non-uniform thickness regions, and particulate-filled polymer matrices. These non-ideal interfacial structures can increase thermal boundary resistance by promoting phonon scattering, reflection, and mode mismatch at the interface. Stated differently, even where a bulk TIM has an advertised thermal conductivity, the effective interfacial region can behave as a phonon barrier because vibrational energy is not efficiently transmitted across discontinuous contact points. In some embodiments of the present disclosure, the permanent solder bonds provide a continuous metallurgical interface across substantially the entire contact area between the bottom ceramic plate of each thermoelectric module and the copper water block, thereby reducing interfacial discontinuities and suppressing phonon-scattering mechanisms associated with paste-based or compressive interfaces.

In some embodiments, phonon coupling across the solder-bonded interface can be characterized as improved vibrational-energy transmission from the thermoelectric module into the copper water block due to intimate contact and reduced acoustic mismatch relative to polymeric or porous interface layers. The solder layer can provide a mechanically continuous pathway with fewer trapped gas pockets and fewer mechanically compliant regions than a TIM layer, thereby enabling more efficient conversion of lattice vibration energy in the thermoelectric module package into heat flow within the copper water block. This improved phonon transmission can reduce thermal boundary resistance at the module-to-water-block interface, which can increase effective heat extraction from the hot side of the thermoelectric modules and improve coefficient of performance (COP) at a given electrical input.

In some embodiments, the linear array configuration of multiple thermoelectric modules on a single copper water block further interacts with phonon-mediated transport by reducing cumulative boundary interfaces. Where discrete module assemblies each include their own TIM layer and associated mounting stack-up, each interface can add an incremental thermal boundary resistance attributable to phonon scattering and imperfect contact. By permanently bonding multiple thermoelectric modules to a unified copper water block, the architecture can reduce the number of distinct interfacial layers that phonon energy must traverse before reaching the liquid-cooled heat-extraction structure. This can be particularly beneficial under high heat flux conditions, where interfacial thermal boundary resistance becomes a domi-nant loss mechanism and can otherwise limit the achievable temperature differential across the thermoelectric modules.

In some embodiments, the internal coolant flow channels disposed beneath the bonded thermoelectric modules can be treated as maintaining a low thermal resistance sink that rapidly removes heat once phonon energy has entered the copper water block. That is, improved phonon coupling at the solder-bonded interface can increase the rate at which heat is injected into the copper substrate, while the liquid circulation can reduce local copper temperature rise and thereby maintain a favorable temperature gradient that sustains continued phonon-driven conduction away from the interface. The combined effect can be a reduction in hot-side temperature of the thermoelectric modules during operation, which can preserve thermoelectric efficiency, reduce electrical power demand for a target payload temperature, and improve stability over extended operating intervals.

In some embodiments, the selection of solder composition and bond geometry can further support phonon-coupled heat transfer by providing a bond layer having high thermal conductivity, mechanical stability under thermal cycling, and reduced propensity for microc-racking or delamination. Microcracks, void formation, and delamination can introduce new discontinuities that increase phonon scattering and raise thermal boundary resistance over time. The disclosed solder-bonded construction can therefore be described as providing a phonon-stable thermal interface that maintains low interfacial resistance through thermal cycling, vibration, and long-duration operation, thereby supporting the stated goals of long-term reliability and sustained COP in portable temperature-controlled applications.

In some embodiments, the thermoelectric cooling assembly is configured to promote phonon-coupled heat transfer from the thermoelectric modules into the copper water block by forming each solder bond as a continuous metallurgical interface across substantially an entire contact area between the bottom ceramic plate of a respective thermoelectric module and the top surface of the copper water block. This continuous metallurgical interface can reduce interfacial discontinuities that would otherwise interrupt lattice vibration transmission across the interface. By maintaining intimate contact over substantially the entire bonded area, the solder-bonded interface can reduce interfacial phonon scattering and thereby reduce thermal boundary resistance between the thermoelectric module and the copper water block, in-creasing hot-side heat extraction efficiency during operation.

In some embodiments, the continuous metallurgical interface is configured to reduce phonon reflection at the interface between the bottom ceramic plate and the copper water block relative to an interface that includes a thermal interface material layer. Thermal interface material layers can include polymeric binder matrices, filler particulates, and trapped gas regions that create a composite structure with multiple internal boundaries and mechanical compliance variations. Such structures can promote phonon reflection and mode mismatch at the interface, thereby increasing thermal boundary resistance and reducing the effective heat flux into the copper substrate. In contrast, the solder bond can provide a mechanically continuous pathway having higher stiffness and fewer internal discontinuities than a thermal interface material layer, enabling more efficient transmission of vibrational energy from the ceramic plate region into the copper water block.

In some embodiments, the solder bond is configured to maintain phonon-coupled thermal conduction under thermal cycling by selecting a solder alloy and bond process that reduces formation of microvoids and interfacial microcracks over repeated heating and cooling cycles. Thermal cycling can cause differential expansion and contraction between the ceramic plate, solder, and copper water block. If the bond is poorly formed or mechanically unstable, the cycling can nucleate voids, fatigue cracks, or localized delamination that introduce new interfacial discontinuities. Such discontinuities can increase phonon scattering and reflection at the interface and thereby increase thermal boundary resistance over time, reducing coefficient of performance and degrading cooling capacity.

Microvoids can be microscopic void spaces (e.g., gas pockets or unfilled volume regions) present within a solder layer and/or at a solder interface. In some embodiments, microvoids can arise from incomplete wetting, flux entrapment, outgassing during reflow, surface contamination, and/or insufficient solder volume. Microvoids can act as thermal discontinuities because the void regions have substantially lower thermal conductivity than the surrounding metallurgical material and can introduce local impedance mismatches that promote phonon scattering and reflection. Accordingly, reducing microvoid density and microvoid size within the solder bond can improve long-term phonon-coupled thermal conduction and reduce growth of thermal boundary resistance.

In some embodiments, the solder alloy is selected to provide high thermal conductivity and stable mechanical behavior across the intended operating temperature range of the thermoelectric cooling assembly. By way of example, the solder alloy can be selected from indium-based solder alloys, tin-silver-based solder alloys, tin-copper-based solder alloys, and combinations thereof, with the selection further based on wetting performance to copper, compatibility with the ceramic plate metallization, and resistance to fatigue cracking under cyclic thermal stress. In some embodiments, the solder bond is formed using a controlled reflow process and surface preparation (e.g., cleaning, activation, and flux control) configured to promote uniform wetting and to reduce microvoid formation, thereby maintaining low interfacial thermal boundary resistance over extended service life.

In some embodiments, the resulting phonon-coupled interface operates in conjunction with the internal liquid coolant circulation of the copper water block, such that heat transferred into the copper substrate via reduced thermal boundary resistance is rapidly removed by the coolant flow channels positioned beneath the bonded module region. This combined architecture can maintain a lower hot-side temperature at the thermoelectric modules, enabling improved thermoelectric efficiency and more stable temperature regulation of the payload chamber over long-duration portable operation.

### Conclusion

Although the present embodiments have been described with reference to specific example embodiments, various modifications and changes can be made to these embodiments without departing from the broader spirit and scope of the various embodiments. For example, the various devices, modules, etc. described herein can be enabled and operated using hardware circuitry, firmware, software or any combination of hardware, firmware, and software (e.g., embodied in a machine-readable medium).

In addition, it can be appreciated that the various operations, processes, and methods disclosed herein can be embodied in a machine-readable medium and/or a machine accessible medium compatible with a data processing system (e.g., a computer system), and can be performed in any order (e.g., including using means for achieving the various operations). Accordingly, the specification and drawings are to be regarded in an illustrative rather than a re-strictive sense. In some embodiments, the machine-readable medium can be a non-transitory form of machine-readable medium.

1. A thermoelectric cooling assembly comprising:
a copper water block having a top surface, a bottom surface, and internal flow channels configured for liquid coolant circulation;
a plurality of thermoelectric modules, each thermoelectric module comprising bismuth telluride semiconductor pellets electrically connected in series by copper traces and disposed between a top ceramic plate and a bottom ceramic plate; and
a plurality of solder bonds, each solder bond permanently attaching said bottom ceramic plate of a respective thermoelectric module directly to said top surface of said copper water block;
wherein said plurality of thermoelectric modules are arranged in a linear array along said top surface of said copper water block, and
wherein said copper water block provides a unified thermal management system wherein waste heat from said plurality of thermoelectric modules is absorbed by liquid coolant circulating through said internal flow channels as part of a closed-loop cooling circuit.

2. The thermoelectric cooling assembly of claim 1, wherein each of said plurality of solder bonds provides a metallurgical connection with thermal resistance less than 0.2 K·cm²/W.

3. The thermoelectric cooling assembly of claim 2, wherein said solder bonds eliminate degradable thermal interface materials between said thermoelectric modules and said copper water block.

4. The thermoelectric cooling assembly of claim 3, wherein said copper water block is fabricated from high-purity copper.

5. The thermoelectric cooling assembly of claim 4, wherein each thermoelectric module of said plurality of thermoelectric modules comprises semiconductor pellets having dimen-sions of approximately 1 mm×1 mm×1 mm.

6. The thermoelectric cooling assembly of claim 5, wherein each thermoelectric module of said plurality of thermoelectric modules comprises 50 pairs of said bismuth telluride semiconductor pellets arranged within a 20 mm×20 mm footprint.

7. The thermoelectric cooling assembly of claim 6, wherein said copper traces have a thickness of approximately 0.05 mm and said top ceramic plate and said bottom ceramic plate of each thermoelectric module each have a thickness of approximately 0.2 mm.

8. The thermoelectric cooling assembly of claim 7, wherein said copper water block further comprises an inlet port and an outlet port in fluid communication with said internal flow channels.

9. The thermoelectric cooling assembly of claim 8, wherein said plurality of thermoelectric modules comprises at least four thermoelectric modules arranged in an end-to-end linear sequence along a longitudinal axis of said copper water block.

10. The thermoelectric cooling assembly of claim 9, wherein each thermoelectric module further comprises a plurality of electrical connection terminals extending from said top ceramic plate, said electrical connection terminals configured to receive electrical power for thermoelectric operation.

11. The thermoelectric cooling assembly of claim 10, wherein said internal flow channels are configured to circulate liquid coolant in continuous liquid phase without phase change during operation.

12. The thermoelectric cooling assembly of claim 11, wherein said solder bonds create a hermetically sealed, mechanically robust assembly resistant to vibration, thermal shock, and mechanical stress.

13. The thermoelectric cooling assembly of claim 12, further comprising:
a closed-loop cooling circuit comprising:
a pump configured to circulate liquid coolant through said internal flow channels of said copper water block;
a radiator in fluid communication with said copper water block, said radiator configured to dissipate heat from said liquid coolant;
a power source electrically connected to said plurality of thermoelectric modules; and
an aluminum payload chamber thermally coupled to said top ceramic plate of each of said plurality of thermoelectric modules.

14. The thermoelectric cooling assembly of claim 13, wherein said aluminum payload chamber is configured to maintain a temperature between 2 °C and 8 °C for storage of temperature-sensitive materials.

15. The thermoelectric cooling assembly of claim 13, further comprising a temperature sensor positioned within said aluminum payload chamber and a controller configured to modulate electrical current to said plurality of thermoelectric modules based on temperature readings from said temperature sensor.

16. The thermoelectric cooling assembly of claim 1, wherein each of said plurality of solder bonds forms a continuous metallurgical interface across substantially an entire contact area between said bottom ceramic plate and said top surface of said copper water block to reduce interfacial phonon scattering and thermal boundary resistance.

17. The thermoelectric cooling assembly of claim 16, wherein said continuous metallurgical interface is configured to reduce phonon reflection at an interface between said bottom ceramic plate and said copper water block relative to a thermal interface material layer disposed between said bottom ceramic plate and said copper water block.

18. The thermoelectric cooling assembly of claim 1, wherein said plurality of solder bonds comprises a solder alloy selected to maintain phonon-coupled thermal conduction across said solder bonds under thermal cycling by reducing formation of microvoids and interfacial microcracks that increase thermal boundary resistance.
